(19) United States
(12) Patent Application Publication
(10) Pub. No.: US 2010/0052154 A1
(43) Pub. Date: Mar. 4, 2010

(54) SURFACE SMOOTHENED ULTRAHIGH CONDUCTIVITY COMPOSITE LID FOR IMPROVED MARKING PERMANENCY OF SEMICONDUCTOR PACKAGED DEVICES

(75) Inventors: Ali Heydari Monfarad, Albany, CA (US); Charles J. Ingalz, San Jose, CA (US)

Correspondence Address: OSHA LIANG L.L.P./SUN, TWO HOUSTON CENTER, 909 FANNIN, SUITE 3500, HOUSTON, TX, 77010, US

(73) Assignee: SUN MICROSYSTEMS, INC., Santa Clara, CA (US)

(21) Appl. No.: 12/201,661

(22) Filed: Aug. 29, 2008

(51) Int. Cl. H01L 23/36; H01L 21/58

(52) U.S. Cl. 257/704; 438/119; 257/E23.101; 257/E21.505

(57) ABSTRACT

A semiconductor-lid structure and method of forming a semiconductor-lid structure includes a semiconductor die, an ultrahigh thermal conductivity lid disposed on the semiconductor die, and a thermal interface layer between said semiconductor die and said ultrahigh thermal conductivity lid. The ultrahigh thermal conductivity lid includes a coupon having at least one uneven surface, a first layer on said at least one uneven surface formed from a process comprising one of sputter coating a highly adhesive metal over said uneven surface and sputtering a metallic seed layer, and a second layer on said first layer formed from a process comprising one of sputtering a metallic diffusion barrier layer over said first layer and electroplating the metallic seed layer with a highly conductive metal. The ultrahigh thermal conductivity lid has a smooth outer surface formed by chemical and/or mechanical processing of the ultrahigh thermal conductivity lid after formation of the second layer.

### BACKGROUND OF INVENTION

1. Field of the Invention

The present invention relates generally to a method for smoothening surfaces of non-metallic and semi-metallic lids disposed over semiconductor dies for use in processor assemblies. More specifically, embodiments of the present invention relate to a processor assembly, where the provision of said surface smoothened lids allows for improved marking permanency and thermal properties of a packaged device including the surface smoothened lids.

2. Background Art

Advanced microprocessors having a relatively large die area exceeding 100 mm² require heat dissipation often in excess of 350 watts. Such high power densities and heat dissipation requirements necessitate the use of a high thermal conductivity lid to contact the microprocessor during heat generation. Additional mechanical requirements such as coplanarity of the lid and thickness of material used to adhere the lid to the semiconductor die are factors to be considered while choosing suitable materials for a lid. With the increasing rate of semiconductor die manufacturing, a need for efficient lid marking also dictates choice of material.

Traditionally, lids made of copper have been employed for smaller semiconductor dies due to low cost and high thermal conductivity qualities of copper. However, for large semiconductor dies, the mismatch in the coefficient of thermal expansion (CTE) between that of copper and the semiconductor may result in high stress at the mechanical interface between the lid and the semiconductor. To mitigate the effect of stress, grease is added as an additional thermal interface from the lid material to the device. To avoid the complexity of attachment and the deficiency of mismatched CTE, alloys consisting of materials such as tungsten, copper, or aluminum are employed in microprocessors or power insulated-gate bipolar transistor (IGBT) devices. The alloy materials possess the advantages of economy of processing and attachment to semiconductor devices, and adequacy of mechanical protection of the semiconductor, thereby allowing for efficient conduction of heat from the semiconductor to a secondary heat rejection device such as a heat sink or a cold plate.

However, due to the inherent compromise of thermal conductivity caused by the employment of alloys, utility of such alloys in high heat dissipating semiconductor devices is limited by thermal performance. Search for a semiconductor-matched CTE in materials has recently led to the development of alternative composite materials such as non-metallic or semi-metallic lids that also possess high thermal conductivity. Typical materials consist of carbon-copper composites, Aluminum Silicon Carbide (AlSiC) composites, Silicon Carbon Diamond (ScD) composites, diamond, and tungsten carbide diamond composites. While these composite materials are more suitable than metallic lids, the composite materials pose challenges in processing and handling due to typically high hardness, difficulty in soldering or brazing, difficulty in accepting permanent marking, and in many cases difficulty in obtaining a flat surface, which is desirable for a good thermal interface.

### SUMMARY OF INVENTION

In general, in one aspect, the invention relates to a semiconductor packaged device comprising: a semiconductor die; an ultrahigh thermal conductivity lid disposed on the semiconductor die, the ultrahigh thermal conductivity lid comprising: a coupon having at least one uneven surface; a first layer on said at least one uneven surface formed from a process comprising one of sputter coating a highly adhesive metal over said uneven surface and sputtering a metallic seed layer; and a second layer on said first layer formed from a process comprising one of sputtering a metallic diffusion barrier layer over said first layer and electroplating the metallic seed layer with a highly conductive metal; and a thermal interface layer between said semiconductor die and said ultrahigh thermal conductivity lid, wherein the ultrahigh thermal conductivity lid has a smooth outer surface formed by at least one of chemical and mechanical processing of the at least one ultrahigh thermal conductivity lid after formation of the second layer.

In general, in one aspect, the invention relates to a method for smoothening surfaces of non-metallic and semi-metallic lids disposed over semiconductor dies for use in processor assemblies, the method comprising: providing at least one lid having at least one uneven surface; forming a first layer on said at least one uneven surface; forming a second layer on said first layer, and at least one of chemical and mechanical processing the at least one lid to provide for a smooth surface finish.

Other aspects and advantages of the invention will be apparent from the following description and the appended claims.

### BRIEF DESCRIPTION OF DRAWINGS

FIG. 1 shows a semiconductor-lid structure in accordance with one or more embodiments of the invention.

FIG. 2 shows a cross-section of a non-metallic or semi-metallic coupon with a jagged outer surface before coating in accordance with one or more embodiments of the invention.

FIG. 3 shows a cross-section of a non-metallic or semi-metallic coupon in accordance with one or more embodiments of the invention after application of the metallic coating.

FIG. 4 is a flow chart showing the steps involved in coating a non-metallic or semi-metallic coupon with a metallic layer in accordance with one or more embodiments of the invention.

### DETAILED DESCRIPTION

Specific embodiments of the invention will now be described in detail with reference to the accompanying figures. Like elements in the various figures are denoted by like reference numerals for consistency.

In the following detailed description of embodiments of the invention, numerous specific details are set forth in order to provide a more thorough understanding of the invention. However, it will be apparent to one of ordinary skill in the art that the invention may be practiced without these specific details. In other instances, well-known features have not been described in detail to avoid unnecessarily complicating the description.

In general, embodiments of the present invention describe a specific method for coating non-metallic or semi-metallic lids with a metallic material or multiple metallic materials for providing a flat surface during solder attachment to a semiconductor die. In one or more embodiments, such a flat surface may allow for easy marking and may provide an ideal surface for solder attachment to a semiconductor.

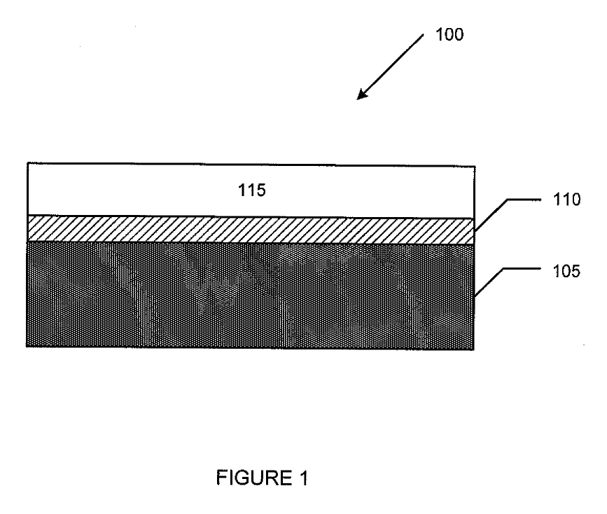

FIG. 1 shows a semiconductor-lid structure 100 in accordance with one or more embodiments of the invention including a semiconductor die substrate 105 onto which a lid 115 is thermally interfaced via an adhesive layer 110 to avoid the thermal stresses associated with direct attachment. The adhesive layer 110 may comprise a layer of grease in cases where traditional lid materials such as copper is employed. In other cases, the adhesive layer 110 may comprise a solder layer where soldering is done to form the solder layer to attach the lid 115 to the semiconductor die 105. The die 105 may be attached via soldering to a ball grid array (BGA) that in turn may be attached to a ceramic or a printed circuit board (PCB) substrate (not shown in FIG. 1). In one or more embodiments of the present invention, the lid may comprise of a monolithic carbonaceous composite, metal matrix composite, or a ceramic matrix composite.

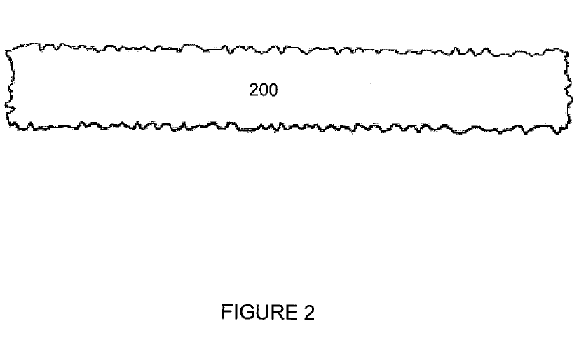

FIG. 2 shows the cross-section of a non-metallic or semi-metallic coupon 200 with a jagged outer surface before coating in accordance with one or more embodiments of the invention. The jagged outer surface renders processing into a flat shape difficult, which may be solved by coating the surface of the coupon with excess metallic material, followed by flattening the surface through mechanical ways such as milling or lapping.

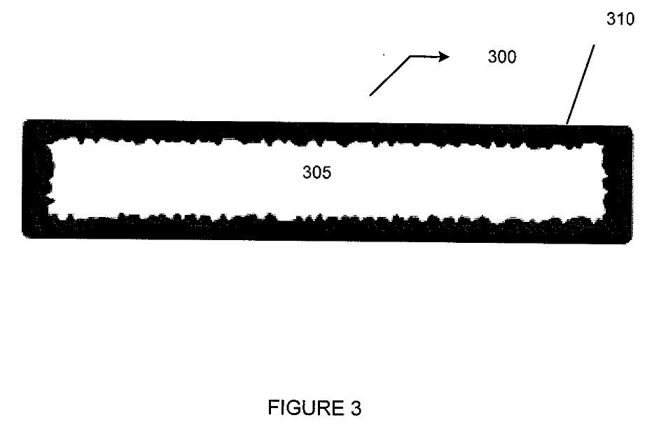

FIG. 3 shows the cross-section of the coupon 300 after application of the metallic coating, where the light area 305 denoting the coupon is coated with a metallic layer 310 shown as a dark area. In one or more embodiments, the smooth outer layer 310 as shown in FIG. 3 may be formed by coating the lid with a layer having thickness sufficient enough to enable subsequent processing steps of flattening the outer coating surfaces 310. This allows for a flat shape of the outer surface of the lid, in spite of the non-uniform substrate material. In one or more embodiments, the processing steps may be tailored to allow for easy repeatability of final flatness of the layer.

In one or more embodiments, the coating process may be performed before attachment of the lid to the processor such that the coupon is processed in environments ideal for preparation of the coupon for coating, but otherwise harmful to semiconductor devices.

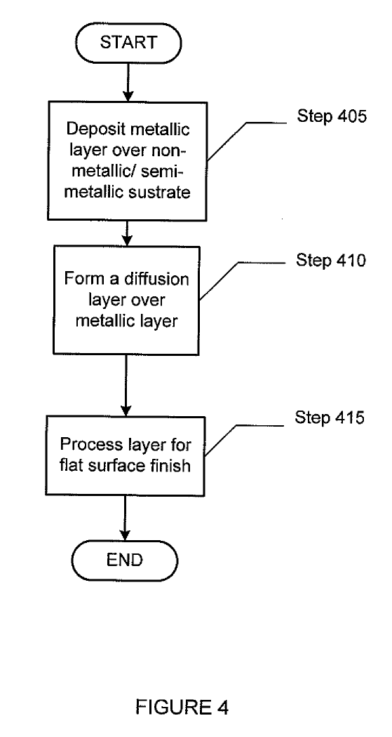

FIG. 4 shows the steps involved in coating a non-metallic or semi-metallic coupon with a metallic layer in accordance with one or more embodiments of the invention. In Step 405, a metallic layer of highly adhesive metal such as Titanium (Ti) or Chromium (Cr) may be sputtered over the non-metallic or semi-metallic substrate coupon with a jagged outer surface. In one or more embodiments, the sputtering may be a physical vapor deposition (PVD) process. In one or more embodiments, the substrate coupon may be cleaned by vacuum sputtering to expose the surface for sputter coating before the sputter coating process. Vacuum sputtering is an etching step under a controlled pressure, and an etching agent, and may be direct current (DC) or radio-frequency (RF) biased. In one or more embodiments, the PVD may be alternated with RF back-sputtering or chemical etching to form a layer of desired thickness.

In one or more embodiments, Step 405 may include sputtering to deposit a seed layer of metal such as Cu to provide good adhesion. In one or more embodiments, formation of the seed layer may include formation of a sputtered barrier layer of adhesive metals such as Ti or Cr as described above, followed by a sputtered adhesion layer of metals such as Cu or Ni, and finally the seed layer of Cu.

In Step 410, a diffusion barrier layer of metals with appropriate material properties such as Ni may be sputtered over the Ti or Cr layer to minimize thermal barriers and mismatch effects. In one or more embodiments in which a seed layer is deposited in step 405, step 410 may include electroplating the seed player with highly conductive metals such as Cu.

Step 415 involves chemical and mechanical post-processing such as lapping and milling for flattening and shaping the outer surface to a desired thickness. In one or more embodiments in which electroplating is used, post-plating processes such as polishing may be performed to attain desired surface finish and properties.

In one or more embodiments, Step 415 may render the surface of the coating suitable for permanent marking via traditional etched laser marking methods or similar technologies by providing for appropriate flatness and surface finish. Step 415 may also render the composite lid suitable for efficient employment in processors by providing for appropriate surface corrosive resistance, minimal thermal conductivity and diffusivity barrier of the coating, and minimal thermal mismatch between coated composite lid, the thermal interface material, semiconductor, and the rest of the electronics package.

It will be obvious to one of ordinary skill in the art that metallic coating is not limited to vapor deposition, sputtering, and/or electroplating, and that a combination of these methods, such as the abovementioned sputtering of a seed layer followed by electroplating, is within the scope of the invention. In one or more embodiments, a goal is to coat non-metallic or semi-metallic lids with metals to reduce thermal expansion and thermal stresses between layers of a packaged server processor unit or central processing unit (CPU) comprising such lids, while maintaining high thermal diffusivity between the layers, and also allowing for improved marking permanency of the ultrahigh thermal conductivity lids.

Additional advantages of embodiments of the invention may include one or more of the following. Dimensional physical tolerance characteristics of the coated ultrahigh thermal conductivity lids may be rendered comparable or better than traditional metallic lids, while thermal conductivity of a packaged processor comprising said lids is improved such that the processor may be able to release heat to the ambience using traditional air cooling techniques, beyond the limits of traditional metal lid processor packages. In one or more embodiments, the lids are rendered lighter than traditional lids, and also possess higher stiffness. In one or more embodiments, the thermal properties may be improved by at least four times in comparison with traditional lids, with tailorable CTE, electrical resistivity, higher stiffness, and strength.

While the invention has been described with respect to an exemplary embodiment of a method for forming a semiconductor-lid structure, those skilled in the art, having benefit of this disclosure, will appreciate that other embodiments can be devised which do not depart from the scope of the invention as disclosed herein. Accordingly, the scope of the invention should be limited only by the attached claims.

What is claimed is:

1. A semiconductor-lid structure comprising:
a semiconductor die;
an ultrahigh thermal conductivity lid disposed on the semiconductor die, the ultrahigh thermal conductivity lid comprising:
a coupon having at least one uneven surface;
a first layer on said at least one uneven surface formed from a process comprising one of sputter coating a highly adhesive metal over said uneven surface and sputtering a metallic seed layer; and
a second layer on said first layer formed from a process comprising one of sputtering a metallic diffusion barrier layer over said first layer and electroplating the metallic seed layer with a highly conductive metal; and
a thermal interface layer between said semiconductor die and said ultrahigh thermal conductivity lid,
wherein the ultrahigh thermal conductivity lid has a smooth outer surface formed by at least one of chemical and mechanical processing of the at least one ultrahigh thermal conductivity lid after formation of the second layer.

2. The semiconductor-lid structure according to claim 1, wherein the thermal interface layer is formed by soldering said ultrahigh thermal conductivity lid to said semiconductor die.

3. The semiconductor-lid structure according to claim 1 wherein the thermal interface layer is formed by brazing said ultrahigh thermal conductivity lid to said one semiconductor die.

4. The semiconductor-lid structure according to claim 1, wherein the thermal interface layer comprises an adhesive material.

5. The semiconductor-lid structure according to claim 1, wherein the lid comprises one of a monolithic carbonaceous composite, metal matrix composite, and a ceramic matrix composite.

6. The semiconductor-lid structure according to claim 1, wherein the first layer comprises a highly adhesive metal.

7. The semiconductor-lid structure according to claim 6, wherein the highly adhesive metal is selected from the group consisting of Ti and Cr.

8. The semiconductor-lid structure according to claim 6, wherein the first layer is formed by sputter coating said highly adhesive metal.

9. The semiconductor-lid structure according to claim 1, wherein the first layer comprises a metallic seed layer.

10. The semiconductor-lid structure according to claim 9, wherein the metallic seed layer further comprises:
a sputtered barrier layer of adhesive metal;
a sputtered adhesion layer of metal on said sputtered barrier layer; and
a final seed layer on said sputtered adhesion layer.

11. The semiconductor-lid structure according to claim 10, wherein the adhesive metal is selected from the group consisting of Ti and Cr.

12. The semiconductor-lid structure according to claim 10, wherein the adhesion layer comprises Cu.

13. The semiconductor-lid structure according to claim 1, wherein the second layer is a metallic diffusion barrier layer.

14. The semiconductor-lid structure according to claim 13, wherein the metallic diffusion barrier layer comprises Ni.

15. The semiconductor-lid structure according to claim 9, wherein the second layer is formed by electroplating the metallic seed layer with a highly conductive metal.

16. The semiconductor-lid structure according to claim 15, wherein the highly conductive metal comprises Cu.

17. A method of forming a semiconductor-lid structure, the method comprising:
providing a coupon having at least one uneven surface;
forming a first layer on said at least one uneven surface by one of sputter coating a highly adhesive metal over said uneven surface and sputtering a metallic seed layer; and
forming a second layer on said first layer by one of sputtering a metallic diffusion barrier layer over said first layer and electroplating the metallic seed layer with a highly conductive metal; and
smoothing an outer surface by at least one of chemical and mechanical processing after formation of the second layer.

18. The method according to claim 17, wherein the at least one of chemical and mechanical processing step comprises at least one of lapping, milling, and polishing.

19. The semiconductor-lid structure according to claim 17, wherein the forming of the first layer comprises:
sputtering a barrier layer of adhesive metal;
sputtering an adhesion layer of metal on said sputtered barrier layer; and
sputtering a final seed layer on said sputtered adhesion layer.
